(19) United States
(12) Patent Application Publication
(10) Pub. No.: US 2026/0215139 A1
(43) Pub. Date: Jul. 23, 2026

(54) Display Device And Electronic Device Including Same

(71) Applicant: Samsung Display Co., Ltd., Yongin-si (KR)

(72) Inventors: Juyoung Yoon, Yongin-si (KR); Dahye Kim, Yongin-si (KR); Junghyun Kim, Yongin-si (KR); Hyun-Hyang Kim, Yongin-si (KR); Hyeonmi Lee, Yongin-si (KR)

(73) Assignee: Samsung Display Co., Ltd., Yongin-si (KR)

(21) Appl. No.: 19/415,942

(22) Filed: Dec. 11, 2025

(30) Foreign Application Priority Data
Jan. 20, 2025 (KR) 10-2025-0007872
May 20, 2025 (KR) 10-2025-0065611

(51) Int. Cl. H10K 59/80; H10K 102/00

(52) U.S. Cl. CPC H10K 59/879; H10K 59/871; H10K 2102/351

(57) ABSTRACT

A display device includes a display panel with a light emitting element and a cover window disposed on the display panel. The cover window includes a flat portion and a bent portion bent from an edge of the flat portion. Further, the cover window includes a base layer and an anti-reflective layer disposed on the base layer, where the anti-reflective layer includes a high refractive index layer and a low refractive index layer disposed on the high refractive index layer. When a light is received on the cover window, a reflectance of the anti-reflective layer decreases as a wavelength of the light increases from about 380 nm to about 450 nm and also from about 500 nm to about 580 nm.

### CROSS-REFERENCE TO RELATED APPLICATIONS

This application claims priority to and the benefit of Korean Patent Application No. 10-2025-0007872, filed on Jan. 20, 2025, and Korean Patent Application No. 10-2025-0065611, filled on May 20, 2025, the disclosures of which are hereby incorporated by reference herein in their entirety.

### TECHNICAL FIELD

The present disclosure relates to a display device and an electronic device. More particularly, the present disclosure relates to a display device with improved reliability and an electronic device that includes such display device.

### BACKGROUND

Various electronic devices, such as televisions, mobile phones, tablet computers, and game devices, are an ongoing focus of research and development. Electronic devices may include a display device that generates images and senses inputs. Display devices may include multiple layers with different refractive indices to improve a display quality. Layers with lower refractive indices reduce reflectance and thus enhance display quality, however, layers with lower refractive indices exhibit poor rigidity and lower scratch resistance.

Accordingly, there is a need for display devices that provide high display quality without overly compromising on rigidity and scratch resistance.

### BRIEF SUMMARY

The present disclosure provides a display device including a cover window with improved display quality. The present disclose also provides an electronic device that includes the contemplated display device.

In some embodiments, a display device includes a display panel with a light emitting element and a cover window disposed on the display panel. The cover window includes a flat portion and a bent portion bent from an edge of the flat portion. Further, the cover window includes a base layer and an anti-reflective layer disposed on the base layer. The anti-reflective layer of the cover window includes a high refractive index layer and a low refractive index layer disposed on the high refractive index layer. When a light is received on the cover window, a reflectance of the anti-reflective layer decreases as a wavelength of the light increases from about 380 nm to about 450 nm and also from about 500 nm to about 580 nm. In some examples, a reflectance of the anti-reflective layer decreases as a wavelength of a light increases in a range where the wavelength of the light is greater than or equal to about 380 nm and smaller than or equal to about 450 nm and greater than or equal to about 500 nm and smaller than or equal to about 580 nm.

In some embodiments, a display device includes a display panel including a light emitting element and a cover window disposed on the display panel. The cover window includes a base layer and an anti-reflective layer disposed on the base layer. The anti-reflective layer includes a first refractive index layer, a second refractive index layer disposed under the first refractive index layer, and a third refractive index layer disposed under the second refractive index layer. The first, second, and third refractive index layers have different refractive indices. The refractive index of the second refractive index layer is greater than the refractive index of the first and third refractive index layers. The first refractive index layer has a first thickness greater than a second thickness of the second refractive index layer, and the second thickness of the second refractive index layer is greater than a third thickness of the third refractive index layer.

In some embodiments, an electronic device includes a display device in which a module area is defined and an electronic module disposed to correspond to the module area. The display device includes a display panel including a light emitting element and a cover window disposed on the display panel and including a flat portion and a bent portion bent from an edge of the flat portion. The cover window includes a base layer and an anti-reflective layer disposed on the base layer, the anti-reflective layer including a high refractive index layer and a low refractive index layer disposed on the high refractive index layer. When a light is received on the cover window, a reflectance of the anti-reflective layer decreases as a wavelength of the light increases from about 380 nm to about 450 nm and also from about 500 nm to about 580 nm. In some examples, a reflectance of the anti-reflective layer decreases as a wavelength of a light increases in a range where the wavelength of the light is greater than or equal to about 380 nm and smaller than or equal to about 450 nm and greater than or equal to about 500 nm and smaller than or equal to about 580 nm.

According to the embodiments described above, the thicknesses of the flat portion and the bent portion of the cover window are different from each other. Nonetheless, even when the bent portion is thinner than the flat portion, tristimulus values remain constant across both the flat and bent portions, and thus color difference between the flat portion and the bent portion is minimized, thereby improving the display quality of the cover window.

### BRIEF DESCRIPTION OF THE DRAWINGS

FIG. 1 is a perspective view of an electronic device according to an embodiment of the present disclosure;

FIG. 2 is an exploded perspective view of the electronic device of FIG. 1;

FIG. 3 is a cross-sectional view of a display device of the electronic device of FIG. 1 taken along a line I-I′ of FIG. 2;

FIG. 4 is a cross-sectional view of a portion of a display panel according to an embodiment of the present disclosure;

FIG. 5A is a cross-sectional view of a display device of the electronic device of FIG. 1 taken along a line II-II′ of FIG. 2;

FIG. 5B is an enlarged view of an area AA′ of the display device of FIG. 5A;

FIGS. 6A to 6C are graphs illustrating embodiment example 2 of Table 1;

FIGS. 7A to 7C are graphs illustrating embodiment example 1 of Table 1; and

FIGS. 8A to 8C are graphs illustrating embodiment example 3 of Table 1.

### DETAILED DESCRIPTION

While specific embodiments are shown in the drawings and described in detail hereinbelow, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In the present disclosure, it will be understood that when a first element (or area, layer, or portion) is referred to as being “on”, “connected to” or “coupled to” a second element or layer, the first element can be directly on, connected or coupled to the second element or layer or intervening elements or layers may be present and disposed in between the first and second elements.

Like numerals refer to like elements throughout the present disclosure, unless otherwise noted. In the drawings, the thickness, ratio, and dimension of components may be exaggerated for effective description of the technical content.

As used herein, the term “and/or” may include any and all combinations of one or more of the associated listed items.

Additionally, the terms “about,” “generally,” and “substantially” are intended to mean, and a person of ordinary skill would understand them to mean that slight deviations from absolute are included within the scope of the term so modified. To the extent numerical values (including values that represent ends of ranges) are described herein with the value being “about” a certain numerical value, such numerical values may deviate up to 5%, 10%, 20%, and 30% from the amount indicated. Thus, for example, if a wavelength is about 380 nm, this may be as low as 361 nm or as high as 399 nm.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another element or feature as shown in the figures.

Unless otherwise defined, all terms including technical and scientific terms used herein have the same meaning as commonly understood by one of ordinary skill in the art to which this disclosure applies. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, embodiments of the present disclosure will be described with reference to the accompanying drawings.

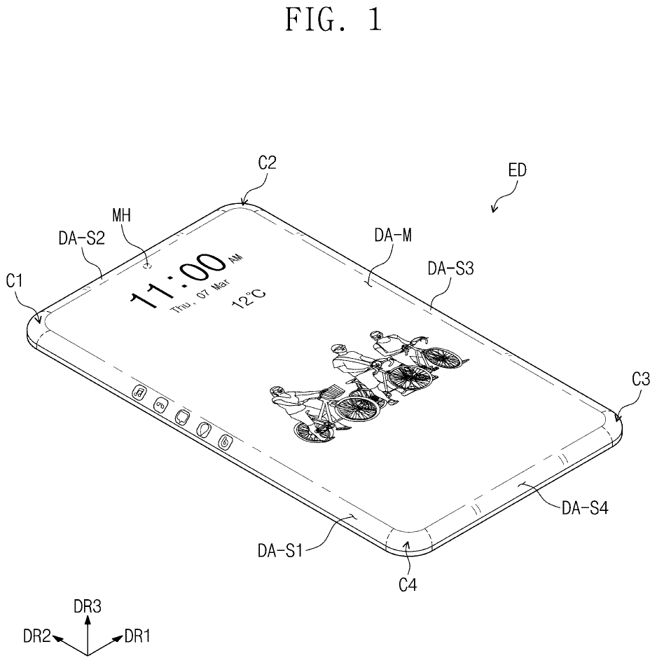

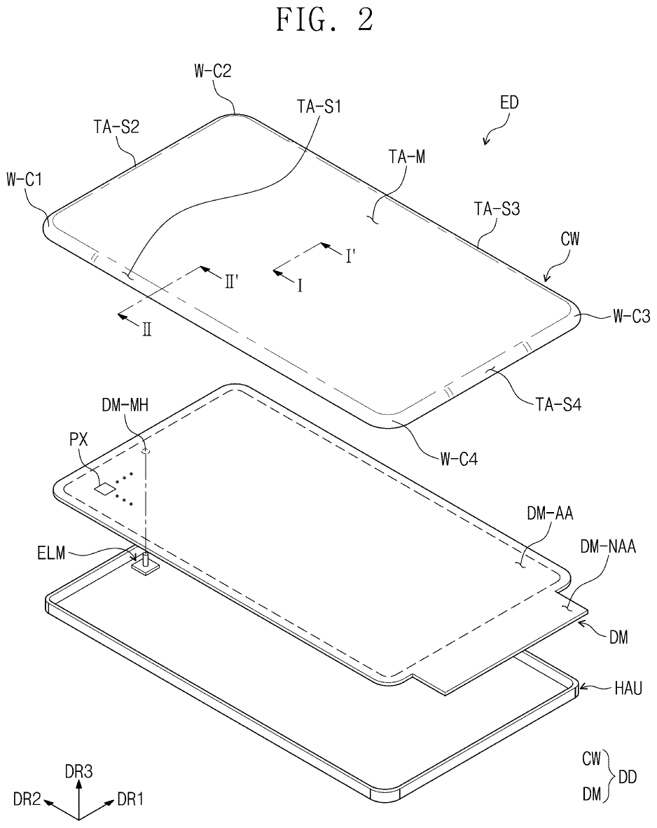

FIG. 1 is a perspective view of an electronic device according to an embodiment of the present disclosure. FIG. 2 is an exploded perspective view of the electronic device of FIG. 1.

The electronic device ED shown in FIG. 1 may be a device that is activated in response to electrical signals. For example, the electronic device ED may be a personal computer, a notebook computer, a personal digital assistant, a game unit, a mobile electronic device, a television set, a monitor, an outdoor billboard, a car navigation unit, or a wearable unit. However, the present disclosure is not be limited thereto or thereby. FIG. 1 shows a smartphone as a representative example of the electronic device ED.

A display area may be defined in the electronic device ED. The electronic device ED may display an image and receive an external input through the display area. The display area of the electronic device ED may include a main display area DA-M and first, second, third, and fourth sub-display areas DA-S1, DA-S2, DA-S3, and DA-S4.

The main display area DA-M may be substantially parallel to a plane defined by a first direction DR1 and a second direction DR2, however, the present disclosure should not be limited thereto or thereby. The main display area DA-M may have a shape concave or convex with respect to the plane defined by the first direction DR1 and the second direction DR2.

The main display area DA-M may display an image in a third direction DR3 that is orthogonal to each of the first direction DR1 and the second direction DR2. The third direction DR3 may be defined as a thickness direction of the electronic device ED. Front (or upper) and rear (or lower) surfaces of each member of the electronic device ED may be opposite to each other in the third direction DR3.

In the present disclosure, the expression “when viewed in a plane” may refer to a state of being viewed in the third direction DR3. In the present disclosure, the expression “on a cross-section” may refer to a state of being viewed in the first direction DR1 or the second direction DR2. Directions indicated by the first, second, and third directions DR1, DR2, and DR3 may be relative to each other, and thus, the directions indicated by any one of the first, second, and third directions DR1, DR2, and DR3 may be used to relate to other directions.

The main display area DA-M may have a rectangular shape with short sides extending in the first direction DR1 and long sides extending in the second direction DR2. However, the shape of the main display area DA-M should not be limited to the rectangular shape, and the main display area DA-M may have a variety of shapes, such as a circular shape, a polygonal shape, etc., when viewed in the plane.

The main display area DA-M may include a sub-area MH as shown in FIGS. 1 and 2. However, this is merely an example, and the arrangement of the sub-area MH is not particularly limited. Further, while FIG. 1 shows one sub-area MH, in some example arrangements, the sub-area MH may be provided as a plurality of sub-areas.

Various electronic modules ELM, such as electronic module ELM shown in FIG. 2, may be arranged to correspond to the sub-area MH. As an example, the electronic module ELM may include at least one of a camera, a speaker, a light sensor, and a thermal sensor. The electronic device ED may include an electronic module ELM that takes a picture of an external object using a visible light passing through the sub-area MH or that determines whether an external object is approaching using an infrared light. The electronic module ELM may include multiple components, but it is limited to such arrangements.

Each of the first, second, third, and fourth sub-display areas DA-S1, DA-S2, DA-S3, and DA-S4 may be bent from the main display area DA-M. Each of the first, second, third, and fourth sub-display areas DA-S1, DA-S2, DA-S3, and DA-S4 may be bent to have a curvature and may include a curved surface. The curvatures of the first, second, third, and fourth sub-display areas DA-S1, DA-S2, DA-S3, and DA-S4 may be the same as each other or two or more of the sub-display areas may have different curvatures from each other.

The main display area DA-M and the first, second, third, and fourth sub-display areas DA-S1, DA-S2, DA-S3, and DA-S4 may be arranged adjacent to each other and may together implement a continuous display area. The first sub-display area DA-S1 and the third sub-display area DA-S3 may extend respectively from the long sides of the main display area DA-M, which are parallel to the second direction DR2, and the second sub-display area DA-S2 and the fourth sub-display area DA-S4 may extend respectively from the short sides of the main display area DA-M, which are parallel to the first direction DR1.

The first sub-display area DA-S1 and the third sub-display area DA-S3 may extend in the second direction DR2 and may be spaced apart from each other in the first direction DR1, and the main display area DA-M may be disposed between the first sub-display area DA-S1 and the third sub-display area DA-S3. The second sub-display area DA-S2 and the fourth sub-display area DA-S4 may extend in the first direction DR1 and may be spaced apart from each other in the second direction DR2, and the main display area DA-M may be disposed between the second sub-display area DA-S2 and the fourth sub-display area DA-S4.

FIG. 1 shows four sub-display areas DA-S1, DA-S2, DA-S3, and DA-S4 respectively extending from four sides of the main display area DA-M as a representative example, however, the present disclosure is not limited thereto or thereby. According to an embodiment, a display area of a display device DD may include a sub-display area that is bent and extends from at least one side of four sides of main display area DA-M. As an example, the display device DD may include only three or fewer of the four sub-display areas DA-S1, DA-S2, DA-S3, and DA-S4.

The electronic device ED may include first, second, third, and fourth display corner portions C1, C2, C3, and C4 disposed between the first, second, third, and fourth sub-display areas DA-S1, DA-S2, DA-S3, and DA-S4. The first, second, third, and fourth sub-display areas DA-S1, DA-S2, DA-S3, and DA-S4 may be connected to the first, second, third, and fourth display corner portions C1, C2, C3, and C4 to surround the main display area DA-M.

The first display corner portion C1 may be disposed between the first sub-display area DA-S1 and the second sub-display area DA-S2 and may connect the first sub-display area DA-S1 and the second sub-display area DA-S2, which respectively extend in directions that intersect each other. Further, the first display corner portion C1 may have a curvature. The second display corner portion C2 may be disposed between the second sub-display area DA-S2 and the third sub-display area DA-S3 and may connect the second sub-display area DA-S2 and the third sub-display area DA-S3, which respectively extend in directions that intersect each other. Further, the second display corner portion C2 may have a curvature. The third display corner portion C3 may be disposed between the third sub-display area DA-S3 and the fourth sub-display area DA-S4 and may connect the third sub-display area DA-S3 and the fourth sub-display area DA-S4, which respectively extend in directions that intersect each other. Further, the third display corner portion C3 may have a curvature. The fourth display corner portion C4 may be disposed between the fourth sub-display area DA-S4 and the first sub-display area DA-S1 and may connect the fourth sub-display area DA-S4 and the first sub-display area DA-S1, which respectively extend in directions that intersect each other. Further, the fourth display corner portion C4 may have a curvature.

The first, second, third, and fourth display corner portions C1, C2, C3, and C4 may correspond to corners of the electronic device ED, respectively. Since each of the first, second, third, and fourth display corner portions C1, C2, C3, and C4 are curved, the corners of the electronic device ED may have a rounded shape rather than angular corners.

Referring to FIG. 2, the electronic device ED may include the display device DD and the electronic module ELM. The display device DD may include a display module DM and a cover window CW disposed on the display module DM. In addition, the electronic device ED may further include a housing HAU that accommodates the display module DM. A module area DM-MH may be defined in the display device DD, and the electronic module ELM may be disposed to correspond to the module area DM-MH. For example, the ELM may be positioned relative to the housing HAU so that when display device DD is assembled to the housing HAU, the electronic module ELM is aligned with the module area DM-MH.

In the electronic device ED shown in FIGS. 1 and 2, the housing HAU may be coupled to the cover window CW to define an exterior of the electronic device ED. The housing HAU may be disposed under the display module DM. The housing HAU may include a material with relatively high rigidity. As an example, the housing HAU may include a plurality of frames and/or plates formed of a glass, plastic, or metal material. The housing HAU may provide an accommodation space. The display module DM may be accommodated in the accommodation space and may be protected from external impacts by the housing HAU.

The cover window CW may be disposed on the display module DM. The cover window CW may be coupled to a display panel DP through a lamination process. The cover window CW may cover the display module DM and may protect the display module DM from external impacts and scratches.

The cover window CW may include an optically transparent insulating material. As an example, the cover window CW may include a base film containing a glass or synthetic resin. The cover window CW may have a single-layer or multi-layer structure. As an example, embodiments of the cover window CW with a multi-layer structure may include synthetic resin films attached to each other with an adhesive or may include a glass film and a synthetic resin film attached to the glass film with an adhesive. The cover window CW may further include functional layers, such as an anti-fingerprint layer, a phase control layer, a hard coating layer, etc., disposed on the base film.

The cover window CW may include a transmission area, and the transmission area of the cover window CW may correspond to the main display area DA-M shown in FIG. 1. The transmission area of the cover window CW may transmit the image provided from the display module DM, and a user may view the image from the outside of the electronic device ED. The cover window CW may include a main transmission surface TA-M and first, second, third, and fourth side transmission surfaces TA-S1, TA-S2, TA-S3, and TA-S4.

The main transmission surface TA-M may correspond to the main display area DA-M shown in FIG. 1. The main transmission surface TA-M may include a plane substantially parallel to the plane defined by the first direction DR1 and the second direction DR2.

Each of the first, second, third, and fourth side transmission surfaces TA-S1, TA-S2, TA-S3, and TA-S4 may be bent from the main transmission surface TA-M with a curvature. Accordingly, each of the first, second, third, and fourth side transmission surfaces TA-S1, TA-S2, TA-S3, and TA-S4 may include a curved surface extending from the main transmission surface TA-M. The first, second, third, and fourth side transmission surfaces TA-S1, TA-S2, TA-S3, and TA-S4 may correspond to the first, second, third, and fourth sub-display areas DA-S1, DA-S2, DA-S3, and DA-S4 shown in FIG. 1, respectively.

The main transmission surface TA-M and the first, second, third, and fourth side transmission surfaces TA-S1, TA-S2, TA-S3, and TA-S4 may be arranged adjacent to each other and may together implement a continuous transmission area. The first side transmission surface TA-S1 and the third side transmission surface TA-S3 may extend in the second direction DR2 and may be spaced apart from each other in the first direction DR1, and the main transmission surface TA-M may be disposed between the first side transmission surface TA-S1 and the third side transmission surface TA-S3. The second side transmission surface TA-S2 and the fourth side transmission surface TA-S4 may extend in the first direction DR1 and may be spaced apart from each other in the second direction DR2, and the main transmission surface TA-M may be disposed between the second side transmission surface TA-S2 and the fourth side transmission surface TA-S4.

The cover window CW may include first, second, third, and fourth window corner portions W-C1, W-C2, W-C3, and W-C4 disposed between the first, second, third, and fourth side transmission surfaces TA-S1, TA-S2, TA-S3, and TA-S4. The first, second, third, and fourth window corner portions W-C1, W-C2, W-C3, and W-C4 may substantially correspond to the first, second, third, and fourth display corner portions C1, C2, C3, and C4 of the display device DD shown in FIG. 1. The first, second, third, and fourth side transmission surfaces TA-S1, TA-S2, TA-S3, and TA-S4 may be connected to the first, second, third, and fourth window corner portions W-C1, W-C2, W-C3, and W-C4 to surround the main transmission surface TA-M.

The first window corner portion W-C1 may connect the first side transmission surface TA-S1 and the second side transmission surface TA-S2, which respectively extend in directions that intersect each other. The second window corner portion W-C2 may connect the second side transmission surface TA-S2 and the third side transmission surface TA-S3, which respectively extend in directions that intersect each other. The third window corner portion W-C3 may connect the third side transmission surface TA-S3 and the fourth side transmission surface TA-S4, which respectively extend in directions that intersect each other. The fourth window corner portion W-C4 may connect the fourth side transmission surface TA-S4 and the first side transmission surface TA-S1, which respectively extend in directions that intersect each other. Each of the first, second, third, and fourth window corner portions W-C1, W-C2, W-C3, and W-C4 may have a curvature such that corners of the cover window CW are curved.

The first side transmission surface TA-S1 and the third side transmission surface TA-S3 may be bent with the same curvature. The second side transmission surface TA-S2 and the fourth side transmission surface TA-S4 may be bent with the same curvature. Each of the first side transmission surface TA-S1 and the third side transmission surface TA-S3 may have the curvature different from the curvature of each of the second side transmission surface TA-S2 and the fourth side transmission surface TA-S4. Accordingly, each window corner portion W-C1, W-C2, W-C3, and W-C4 may be formed as a multi-curvature portion having different curvatures by connecting the first and third side transmission surfaces TA-S1 and TA-S3, which extend in the second direction DR2 and define the long sides of the cover window CW, and the second and fourth side transmission surfaces TA-S2 and TA-S4, which extend in the first direction DR1 and define the short sides of the cover window CW.

The display module DM may be activated in response to electrical signals. As shown in FIG. 1, the activated display module DM may display the image through the main display area DA-M of the electronic device ED. Further, and as shown in FIG. 2, the display module DM may include an active area DM-AA, a peripheral area DM-NAA, and the module area DM-MH.

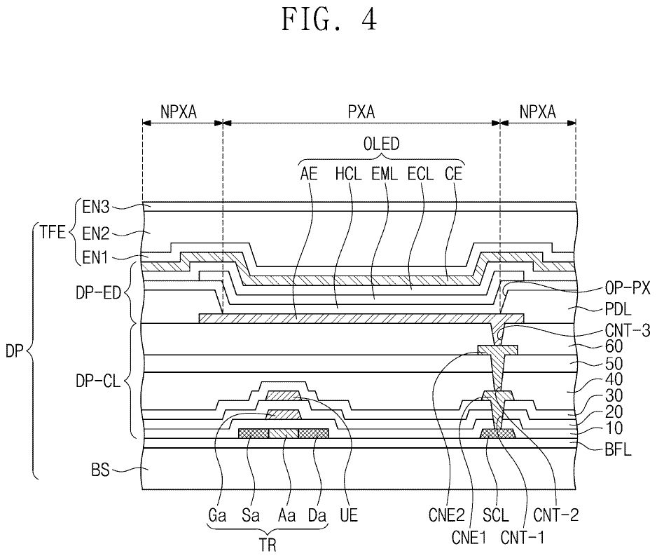

The active area DM-AA may be activated in response to the electrical signals. A pixel PX may be disposed in the active area DM-AA. The pixel PX may include a transistor TR and a light emitting element OLED, which are shown in FIG. 4 and described in greater detail below. The peripheral area DM-NAA may be defined adjacent to at least one side of the active area DM-AA. Circuits or lines to drive the active area DM-AA may be arranged in the peripheral area DM-NAA.

The module area DM-MH may correspond to the sub-area MH shown in FIG. 1. An optical signal, e.g., a visible light or an infrared light, may pass through the module area DM-MH. The module area DM-MH may be defined inside the active area DM-AA. According to an embodiment, the module area DM-MH may be surrounded by the peripheral area DM-NAA or may be surrounded by the active area DM-AA and the peripheral area DM-NAA.

The electronic module ELM may be an electronic component that outputs or receives the optical signal. The electronic module ELM may include a camera module and/or a proximity sensor. The camera module may take a picture of an external object through the module area DM-MH.

Although not shown in the figures, the display device DD may, in some embodiments, further include an optical layer disposed between the display module DM and the cover window CW. The optical layer may be formed on the display module DM through a continuous process. The optical layer may include a polarizing plate or a color filter layer. As an example, the optical layer may include at least one of a retarder, a polarizer, a polarizing film, and a polarizing filter. According to an embodiment, the optical layer may include a plurality of color filters arranged in a selected arrangement. As an example, the color filters may be arranged by taking into account emission colors of the pixels PX. In addition, the optical layer may further include a black matrix disposed adjacent to the color filters.

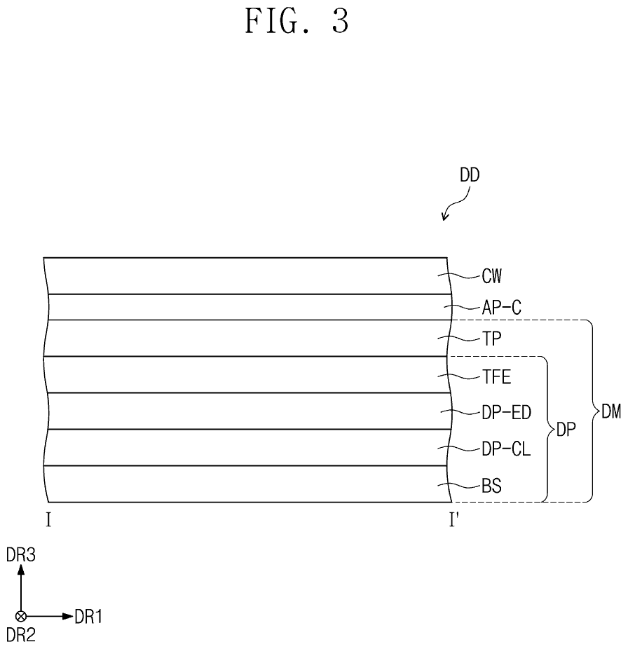

FIG. 3 is a cross-sectional view of the display device DD taken along a line I-I′ of FIG. 2. For ease of explanation, the housing HAU shown in FIG. 2 is omitted in FIG. 3.

Referring to FIG. 3, the display module DM may include the display panel DP and an input sensing part TP disposed on the display panel DP. The display panel DP may have a configuration that substantially generates the image.

The display panel DP may include a base substrate BS, a circuit element layer DP-CL, a display element layer DP-ED, and an encapsulation layer TFE, which are sequentially stacked. According to some embodiments, a separate member may further be disposed between two layers adjacent to each other among the base substrate BS, the circuit element layer DP-CL, the display element layer DP-ED, and the encapsulation layer TFE.

The base substrate BS may provide a base surface on which the circuit element layer DP-CL is disposed. The base substrate BS may be a flexible substrate that is bendable, foldable, or rollable. The base substrate BS may be a glass substrate, a metal substrate, or a polymer substrate, however, it is not limited thereto or thereby. According to some embodiments, the base substrate BS may be an inorganic layer, an organic layer, or a composite material layer.

The circuit element layer DP-CL may be disposed on the base substrate BS. The circuit element layer DP-CL may include an insulating layer, a semiconductor pattern, a conductive pattern, and a signal line. The display element layer DP-ED may be disposed on the circuit element layer DP-CL. The display element layer DP-ED may include the light emitting element OLED, as shown in FIG. 4 and described in greater detail below. In some examples, the light emitting element OLED may include an organic light emitting material, an inorganic light emitting material, an organic-inorganic light emitting material, a quantum dot, or a quantum rod. In some examples, the light emitting element OLED may include a micro-LED or a nano-LED.

The encapsulation layer TFE may be disposed on the display element layer DP-ED. The encapsulation layer TFE may protect the display element layer DP-ED from moisture, oxygen, and foreign substances such as dust particles. The encapsulation layer TFE may include at least one inorganic layer. As an example, the encapsulation layer TFE may include an inorganic layer, an organic layer, and an inorganic layer, which are sequentially stacked.

The input sensing part TP may be disposed on the display panel DP. The input sensing part TP may be disposed directly on the encapsulation layer TFE, however, the present disclosure is not limited thereto or thereby. According to an embodiment, an adhesive member may be disposed between the input sensing part TP and the display panel DP.

In the present disclosure, the expression “one component is disposed/provided/formed directly on another component” means that no third component is disposed between the one component and the another component. For example, when one component is “directly disposed/provided/formed” on another component, it means that the one component and the another component are in “contact” with each other.

With continued reference to FIG. 3, the input sensing part TP may sense an external input, may convert the sensed external input to a selected input signal, and may provide the input signal to the display panel DP. As an example, the input sensing part TP may be a touch sensing part that senses a touch event. The input sensing part TP may sense a direct touch by a user, an indirect touch by a user, a direct touch by an object, or an indirect touch by an object.

The input sensing part TP may sense at least one of the position of the touch event applied from the outside and the intensity (pressure) of the touch event applied from the outside. The input sensing part TP may have various structures or may include various materials, and it should not be particularly limited. As an example, the input sensing part TP may sense the external input in a capacitive method. The display panel DP may receive the input signal from the input sensing part TP and may generate the image corresponding to the input signal.

The display device DD may further include an adhesive layer AP-C disposed between the display module DM and the cover window CW. The display module DM may be coupled to the cover window CW by the adhesive layer AP-C. The adhesive layer AP-C may include a pressure sensitive adhesive (PSA), an optically clear adhesive (OCA) film, or an optically clear adhesive resin (OCR) layer, however, the present disclosure is not limited thereto or thereby. According to some embodiments, the adhesive layer AP-C may be omitted.

FIG. 4 is a cross-sectional view of a portion of the display panel according to an embodiment of the present disclosure. FIG. 4 shows the configuration of the display panel DP in more detail compared to FIG. 3. Hereinafter, description of details of the elements already described with reference to FIG. 3 will not be repeated.

The display panel DP may include a plurality of pixels. Each of the pixels may include at least one transistor TR and the light emitting element OLED. FIG. 4 shows an area of the display panel DP in which the transistor TR and the light emitting element OLED of one pixel among the pixels are disposed. Referring to FIG. 4, the display panel DP may include the base substrate BS, the circuit element layer DP-CL, the display element layer DP-ED, and the encapsulation layer TFE.

The base substrate BS may provide the base surface on which the circuit element layer DP-CL is disposed. The base substrate BS may include a synthetic resin layer. The synthetic resin layer may be formed on a support substrate used when the display panel DP is manufactured, and a conductive layer and an insulating layer may be formed on the synthetic resin layer. Then, the support substrate may be removed, and the synthetic resin layer from which the support substrate is removed may correspond to the base substrate BS.

One or more inorganic layers may be disposed on an upper surface of the base substrate BS. The inorganic layers may form a barrier layer and/or a buffer layer. FIG. 4 shows a structure in which the buffer layer BFL is disposed on the base substrate BS. The buffer layer BFL may increase an adhesion between the base substrate BS and the semiconductor pattern of the circuit element layer DP-CL.

The circuit element layer DP-CL may be disposed on the buffer layer BFL. The circuit element layer DP-CL may include at least one insulating layer and a circuit element. The circuit element may include a signal line, a pixel driving circuit, or the like. An insulating layer, a semiconductor layer, and a conductive layer may be formed by a coating or depositing process. Then, the insulating layer, the semiconductor layer, and the conductive layer may be patterned by a photolithography process, and the circuit element layer DP-CL may be formed.

In the present embodiment, the circuit element layer DP-CL may include the transistor TR, a connection signal line SCL, connection electrodes CNE1 and CNE2, and a plurality of insulating layers. The insulating layers may include first, second, third, fourth, fifth, and sixth insulating layers 10, 20, 30, 40, 50, and 60 sequentially stacked on the buffer layer BFL. Each of the first to sixth insulating layers 10, 20, 30, 40, 50, 60 may include one of an inorganic layer and an organic layer.

The transistor TR may include the semiconductor pattern including a source area Sa, an active area Aa, and a drain area Da and a gate electrode Ga. The semiconductor pattern of the transistor TR may include polysilicon, however, it is not limited thereto or thereby. According to an embodiment, the semiconductor pattern may include amorphous silicon or a metal oxide.

The semiconductor pattern may include a plurality of areas distinguished from each other depending on conductivity. As an example, the semiconductor pattern may have an electrical property that varies depending on whether it is doped or not, or whether a metal oxide is reduced or not. An area of the semiconductor pattern, which has a relatively high conductivity, may serve as an electrode or a signal line, and may correspond to the source area Sa and the drain area Da of the transistor TR. A non-doped or non-reduced area of the semiconductor pattern, which has a relatively low conductivity, may correspond to the active area Aa (or a channel area) of the transistor TR.

The connection signal line SCL may be formed from the semiconductor pattern, and the connection signal line SCL, the source area Sa, the active area Aa, and the drain area Da of the transistor TR may be disposed at the same layer. According to an embodiment, the connection signal line SCL may be electrically connected to the drain area Da of the transistor TR when viewed in a plane.

The first insulating layer 10 may cover the semiconductor pattern of the circuit element layer DP-CL. The gate electrode Ga may be disposed on the first insulating layer 10. The gate electrode Ga may overlap the active area Aa when viewed in the plane. The gate electrode Ga may serve as a mask in a process of doping the semiconductor pattern. An upper electrode UE may be disposed on the second insulating layer 20. The upper electrode UE may overlap the gate electrode Ga.

A first connection electrode CNE1 and a second connection electrode CNE2 may be disposed between the transistor TR and the light emitting element OLED and may electrically connect the transistor TR to the light emitting element OLED. The first connection electrode CNE1 may be disposed on the third insulating layer 30 and may be connected to the connection signal line SCL via a contact hole CNT-1 defined through the first, second, and third insulating layers 10, 20, and 30. The second connection electrode CNE2 may be disposed on the fifth insulating layer 50 and may be connected to the first connection electrode CNE1 via a contact hole CNT-2 defined through the fourth and fifth insulating layers 40 and 50.

The display element layer DP-ED may be disposed on the circuit element layer DP-CL. The display element layer DP-ED may include the light emitting element OLED and a pixel definition layer PDL. The light emitting element OLED may include a first electrode AE, a second electrode CE, and an intermediate layer disposed between the first electrode AE and the second electrode CE. The first electrode AE and the second electrode CE may include a conductive material. The intermediate layer may include at least one organic layer, and according to the present embodiment, the intermediate layer may include a hole control layer HCL, a light emitting layer EML, and an electron control layer ECL, however, it is not limited thereto or thereby. According to some embodiments, the intermediate layer may include an additional layer in addition to the hole control layer HCL, the light emitting layer EML, and the electron control layer ECL. Additionally, in some embodiments, at least one of the hole control layer HCL, the light emitting layer EML, and the electron control layer ECL may be omitted. Further, it should be appreciated that these embodiments are not limiting.

The first electrode AE and the pixel definition layer PDL may be disposed on the sixth insulating layer 60. The first electrode AE may be connected to the second connection electrode CNE2 via a contact hole CNT-3 defined through the sixth insulating layer 60. A light emitting opening OP-PX may be defined through the pixel definition layer PDL to expose at least a portion of the first electrode AE, and the portion of the first electrode AE exposed through the light emitting opening OP-PX may correspond to a light emitting area PXA. A non-light-emitting area NPXA may surround the light emitting area PXA.

The hole control layer HCL and the electron control layer ECL may be commonly disposed in the light emitting area PXA and the non-light-emitting area NPXA. The light emitting layer EML may be formed in a patterned shape to correspond to the light emitting opening OP-PX. The light emitting layer EML having the patterned shape may be formed using a deposition apparatus.

Different from the hole control layer HCL and the electron control layer ECL, each having a film shape, the light emitting layer EML may be deposited in a different way. As an example, the hole control layer HCL and the electron control layer ECL may be commonly formed in the respective pixels using a mask referred to as an open mask. The light emitting layer EML may be formed differently for each of the pixels using a mask referred to as a fine metal mask (FMM).

The encapsulation layer TFE may include a plurality of thin layers. The encapsulation layer TFE may include first, second, and third thin layers EN1, EN2, and EN3 that are sequentially stacked. Each of the first, second, and third thin layers EN1, EN2, and EN3 may include one of the inorganic layer and the organic layer. The inorganic layer may protect the light emitting element OLED from moisture and/or oxygen. The organic layer may protect the light emitting element OLED from foreign substances such as dust particles. However, the configurations of the encapsulation layer TFE are not limited thereto or thereby as long as the light emitting element OLED is protected and/or a light emitting efficiency is improved.

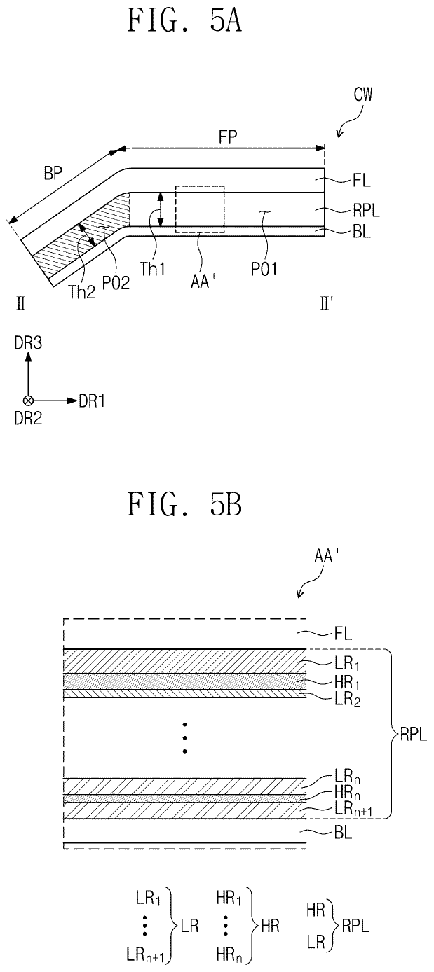

FIG. 5A is a cross-sectional view of the display device taken along a line II-II′ of FIG. 2. FIG. 5B is an enlarged view of an area AA′ of FIG. 5A. The area AA′ may be an enlarged area of a first portion PO1 of an anti-reflective layer RPL.

Referring to FIG. 5A, the cover window CW may include a base layer BL, the anti-reflective layer RPL disposed on the base layer BL, and a functional layer FL disposed on the anti-reflective layer RPL. Although not shown in the figures, an adhesive layer may further be disposed between the anti-reflective layer RPL and the functional layer FL. The cover window CW according to the present disclosure may include a flat portion FP and a bent portion BP bent from an edge of the flat portion FP. The flat portion FP may correspond to the main transmission surface TA-M shown in FIG. 2, and the bent portion BP may correspond to the first side transmission surface TA-S1 shown in FIG. 2.

The base layer BL may provide a base surface on which the anti-reflective layer RPL is disposed. The base layer BL may include a glass or polymer film. As an example, the base layer BL may be a flexible polymer film. The base layer BL may include at least one of polyethylene terephthalate, polyimide, polyacrylate, polymethylmethacrylate, polycarbonate, polyethylenenaphthalate, polyvinylidene chloride, polyvinylidene difluoride, polystyrene, and ethylene vinylalcohol copolymer, however, these materials are merely examples of possible materials, and the composition of base layer BL is not limited thereto or thereby.

The anti-reflective layer RPL may have the first portion PO1 corresponding to the flat portion FP and may have a second portion PO2 corresponding to the bent portion BP. A thickness of the first portion PO1 of the anti-reflective layer RPL may be a first thickness Th1 and a thickness of the second portion PO2 of the anti-reflective layer RPL may be a second thickness Th2. According to some embodiments, the first thickness Th1 may be different from the second thickness Th2. The first thickness Th1 may be greater than the second thickness Th2. The anti-reflective layer RPL may be formed through a deposition process. The difference between the first thickness Th1 and the second thickness Th2 may increase depending on a degree to which a portion of the anti-reflective layer RPL corresponding to the bent portion BP is bent. Specifically, as the portion of the anti-reflective layer RPL corresponding to the bent portion BP is bent to a greater extent, the difference between the first thickness Th1 and the second thickness Th2 may increase. Accordingly, a reflectance of the portion of the anti-reflective layer RPL corresponding to the bent portion BP with respect to an external light may be different from a reflectance of the portion of the anti-reflective layer RPL corresponding to the flat portion FP with respect to the external light.

The cover window CW may further include an auxiliary layer (not shown) disposed between the base layer BL and the anti-reflective layer RPL. The auxiliary layer (not shown) may increase an adhesion between the base layer BL and the anti-reflective layer RPL and may improve mechanical properties, e.g., a wear resistance, of the cover window CW. As an example, the auxiliary layer (not shown) may include oxide silicon.

The functional layer FL may include a polymer film. In some examples, the functional layer FL may include at least one of an antistatic agent, a hard coating agent, and an anti-fingerprint agent. In one specific example, the functional layer FL may include perfluoropolyether (PFPE). Alternatively, in some examples, the functional layer FL may be omitted.

Referring to FIG. 5B, the anti-reflective layer RPL may include a high refractive index layer HR and a low refractive index layer LR. The high refractive index layer HR may have a refractive index greater than or equal to about 1.7 and smaller than or equal to about 2.5. The high refractive index layer HR may include a nitride containing silicon (Si). In some examples, the high refractive index layer HR may include at least one of silicon nitride (SiN_{X}), silicon aluminum nitride (SiAlN), aluminum nitride (AlN), germanium dioxide (GeO₂), zirconium dioxide (ZrO₂), and titanium dioxide (TiO₂). However, these are merely examples, and the high refractive index layer HR may include any known material with a high refractive index without limitation.

The low refractive index layer LR may have a refractive index greater than or equal to about 1.3 and smaller than or equal to about 1.7. The low refractive index layer LR may include an oxide containing silicon (Si) and/or an oxide containing aluminum (Al). In some examples, the low refractive index layer LR may include at least one of silicon oxide (SiO_{X}), aluminum oxide (Al₂O₃), and silicon oxynitride (SiON). The low refractive index layer LR may include silicon dioxide (SiO₂), however, the present disclosure is not limited thereto or thereby. Accordingly, in still further examples, the low refractive index layer LR may further include any known material with a low refractive index.

The high refractive index layer HR may be made up of a plurality of individual layers (plurality of high refractive index layers), e.g., high refractive index layers HR₁, . . . , HRₙ. The low refractive index layer LR may be made up of a plurality of individual layers (plurality of low refractive index layers), e.g., low refractive index layers LR₁, . . . , LRₙ₊₁. In this case, n is an integer greater than or equal to 2. The high refractive index layers HR₁, . . . , HRₙ may have different thicknesses from each other. The low refractive index layers LR₁, . . . , LRₙ₊₁ may have different thicknesses from each other.

The anti-reflective layer RPL including the high refractive index layers HR₁, . . . , HRₙ and the low refractive index layers LR₁, . . . , LRₙ₊₁ may reduce reflectance through destructive interference due to the differences in refractive index. Accordingly, the cover window CW including the anti-reflective layer RPL may have a low reflectance and may improve the display quality of the display device DD, such as the display device DD shown in FIG. 2. The high refractive index layers HR₁, . . . , HRₙ may be arranged alternately with the low refractive index layers LR₁, . . . , LRₙ₊₁. In this manner, each high refractive index layer may be separated by a low refractive index layer so that no two high refractive index layers or low refractive index layers are directly adjacent to each other.

In some examples, the anti-reflective layer RPL may include a first refractive index layer, a second refractive index layer disposed under the first refractive index layer, and a third refractive index layer disposed under the second refractive index layer. The first refractive index layer may correspond to a first low refractive index layer LR₁ disposed at an uppermost position of the anti-reflective layer RPL, the second refractive index layer may correspond to a first high refractive index layer HR₁ disposed under the first low refractive index layer LR₁, and the third refractive index layer may correspond to a second low refractive index layer LR₂ disposed under the first high refractive index layer HR₁.

The first low refractive index layer LR₁ may have the thickness greater than the thickness of each of the first high refractive index layer HR₁ and the second low refractive index layer LR₂. In addition, the thickness of the first high refractive index layer HR₁ may be greater than the thickness of the second low refractive index layer LR₂. As an example, the thickness of the first low refractive index layer LR₁ may be greater than or equal to about 80 nm and smaller than or equal to about 100 nm, the thickness of the first high refractive index layer HR₁ may be greater than or equal to about 50 nm and smaller than or equal to about 80 nm, and the thickness of the second low refractive index layer LR₂ may be greater than or equal to about 5 nm and smaller than or equal to about 30 nm. The first low refractive index layer LR₁ may have a refractive index greater than or equal to about 1.45 and smaller than or equal to about 1.5, the first high refractive index layer HR₁ may have a refractive index greater than or equal to about 1.8 and smaller than or equal to about 2.1, and the second low refractive index layer LR₂ may have a refractive index greater than or equal to about 1.45 and smaller than or equal to about 1.7.

In some variations of the examples that include a first low refractive index layer LR₁, a first high refractive index layer HR₁ and a second low refractive index layer LR₂, the first low refractive index layer LR₁ may include silicon dioxide (SiO₂), the first high refractive index layer HR₁ may include zirconium dioxide (ZrO₂), tantalum pentoxide (Ta₂O₅), and silicon nitride (Si₃N4₎, and the second low refractive index layer LR₂ may include silicon dioxide (SiO₂) and alumina (Al₂O₃).

TABLE 1

| Comparative | | | Embodiment | | Embodiment | | Embodiment | |
|---|---|---|---|---|---|---|---|---|
| example | | | example 1 | | example 2 | | example 3 | |
| | refractive | Thickness | refractive | Thickness | refractive | Thickness | refractive | Thickness |
| | index | (nm) | index | (nm) | index | (nm) | index | (nm) |
| first | 1.48 | 87 | 1.48 | 93 | 1.48 | 95 | 1.47 | 90 |
| layer | | | | | | | | |
| second | 2.05 | 165 | 1.89 | 65 | 2.05 | 60 | 1.98 | 72 |
| layer | | | | | | | | |
| third | 1.48 | 15 | 1.61 | 8 | 1.48 | 10 | 1.64 | 10 |
| layer | | | | | | | | |
| fourth | 2.05 | 58 | 1.89 | 15 | 2.05 | 75 | 1.98 | 49 |
| layer | | | | | | | | |
| fifth | 1.48 | 13 | 1.61 | 25 | 1.48 | 45 | 1.64 | 20 |
| layer | | | | | | | | |
| sixth | 2.05 | 179 | 1.89 | 36 | 2.05 | 18 | 1.98 | 9 |
| layer | | | | | | | | |
| seventh | 1.48 | 24 | 1.48 | 65 | 1.48 | 70 | 1.47 | 41 |
| layer | | | | | | | | |
| eighth | 2.05 | 33 | 1.89 | 10 | — | — | 1.98 | 15 |
| layer | | | | | | | | |
| ninth | 1.48 | 51 | 1.48 | 82 | — | — | 1.47 | 71 |
| layer | | | | | | | | |
| tenth | 2.05 | 12 | — | — | — | — | — | — |
| layer | | | | | | | | |

| R % | | 0.44 | 0.91 | 0.86 | 0.65 |
|---|---|---|---|---|---|
| Reference | a* | 2.1 | 0.1 | −1.0 | 0.1 |
| color | b* | −5.3 | −0.9 | −0.8 | 1.1 |
| coordinates | | | | | |

| | | | | |
|---|---|---|---|---|
| color difference | 9.0 | 0.8 | 1.5 | 0.8 |
| when thickness is | | | | |
| reduced by 10% | | | | |
| color difference | 14.5 | 2.3 | 1.3 | 1.8 |
| when thickness is | | | | |
| reduced by 20% | | | | |

Table 1 above shows the results obtained by performing tests to evaluate cover windows of a comparative example and various non-limiting example embodiments arranged based on the principles of the present disclosure. In evaluating the cover window of each example, a spectrum colorimeter CM-3700A (Konica Minolta, Inc.) was used. According to the comparative example, among first to tenth layers, the first layer, a third layer, a fifth layer, a seventh layer, and a ninth layer are the low refractive index layer containing silicon oxide (SiOx), and a second layer, a fourth layer, a sixth layer, an eighth layer, and the tenth layer are the high refractive index layer containing silicon nitride (SiNx). The example embodiments of the present disclosure, also referred to herein as “embodiment examples,” each included a subset of layers from among the first to tenth layers, and there is a difference in the refractive index and thickness of each layer of the embodiment examples compared to the comparative example.

Referring to embodiment example 2 as a representative example, the first layer may have a thickness greater than or equal to about 90 nm and smaller than or equal to about 100 nm, the second layer may have a thickness greater than or equal to about 50 nm and smaller than or equal to about 60 nm, the third layer may have a thickness greater than or equal to about 7 nm and smaller than or equal to about 13 nm, the fourth layer may have a thickness greater than or equal to about 70 nm and smaller than or equal to about 80 nm, the fifth layer may have a thickness greater than or equal to about 40 nm and smaller than or equal to about 50 nm, the sixth layer may have a thickness greater than or equal to about 17 nm and smaller than or equal to about 20 nm, the seventh layer may have a thickness greater than or equal to about 70 nm and smaller than or equal to about 90 nm. When examining the ratio of each layer's thickness to that of the second layer (taken as 1), the first layer may have a thickness ratio greater than or equal to about 1.25 and smaller than or equal to about 1.68, the third layer may have a thickness ratio greater than or equal to about 0.12 and smaller than or equal to about 0.26, the fourth layer may have a thickness ratio greater than or equal to about 0.23 and smaller than or equal to about 1.37, the fifth layer may have a thickness ratio greater than or equal to about 0.27 and smaller than or equal to about 0.89, the sixth layer may have a thickness ratio greater than or equal to about 0.12 and smaller than or equal to about 0.56, and the seventh layer may have a thickness ratio greater than or equal to about 0.56 and smaller than or equal to about 1.55.

When comparing the above noted thickness ratios, inclusive of each of embodiment examples 1, 2 and 3, with those of the comparative example, it is apparent that a thickness ratio of each low refractive index layer relative to the first high refractive index layer in each of the embodiment examples 1, 2 and 3 is much higher than the thickness ratio of the same layers in the comparative example. For instance, using the values in Table 1 for illustration purposes, the thickness ratio between the first layer (LR₁) and the second layer (HR₁) is 1.583 for embodiment example 2, while it is 0.527 for the comparative example. Further, the thickness ratio between the fifth layer (LR₃) and the second layer (HR₁) is 0.750 for embodiment example 2, while it is 0.079 for the comparative example. In the above respect, the thickness ratios for each of the embodiment examples 1, 2 and 3 are generally similar. Accordingly, the tristimulus values remain consistent across different bending angles, and the color difference between the flat and bent areas is reduced, resulting in improved display quality.

In Table 1, R denotes a reflectance value measured as a percentage, and a* and b* denote color coordinates, indicating cross-sectional color coordinates. In addition, “the color difference when the thickness is reduced by 10%” refers to the color difference when the thickness in the cross-section is reduced by 10%, “the color difference when the thickness is reduced by 20%” refers to the color difference when the thickness in the cross-section is reduced by 20%. In some examples, a reduced thickness may be present in a display with a bent portion and a main portion, where then bent portion is bent relative to the main portion and has a reduced thickness relative to the main portion. This is described in greater detail below. The color difference is calculated by the following equation 1.

$$color difference = {[ {( Δ {a}^{*} )}^{2} + {( Δ {b}^{*} )}^{2} ]}^{1 / 2} \qquad Equation 1$$

Referring to Table 1, it is observed that the reflectance of the cover windows of embodiment examples 1 to 3 is higher compared to the reflectance of the cover window of the comparative example. In addition, compared to the cover window of the comparative example, the cover windows of the embodiment examples 1 to 3 show the color difference within a range from 0.8 to 1.5 when the thickness is reduced by 10% and show the color difference within a range from 1.3 to 2.3 when the thickness is reduced by 20%. These results indicate that the color difference is low in embodiment examples 1 to 3, and that it is much lower than in the comparative example.

To further illustrate the above, we return to FIG. 5A, where the anti-reflective layer RPL may have the flat portion FP with the first thickness Th1 and the bent portion BP with the second thickness Th2, where the second thickness Th2 may be smaller than the first thickness Th1. Accordingly, when a cover window is arranged in a manner such as that of the comparative example, a color difference may occur between the portion of the anti-reflective layer RPL that corresponds to the flat portion FP, and the portion of the anti-reflective layer RPL that corresponds to the bent portion BP. However, referring to embodiment examples 1 to 3 of the present disclosure, even when the thickness of the cover window is reduced by 10% or 20%, e.g., in a bent portion relative to a flat portion, the color difference may be minimal when compared to the comparative example. Thus, the color perceived from the portion corresponding to the flat portion FP of the anti-reflective layer RPL and the color perceived from the portion corresponding to the bent portion BP of the anti-reflective layer RPL may be the same. That is, the cover window CW of the present disclosure may have excellent reflectance, i.e., low levels of reflected light, while providing improved display quality throughout a display area inclusive of regions having different thicknesses.

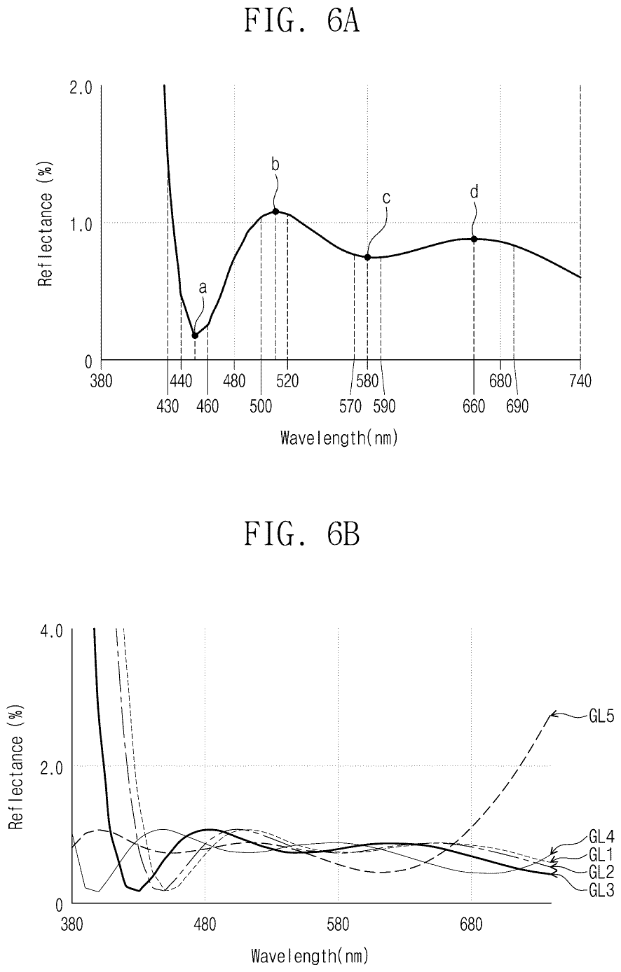

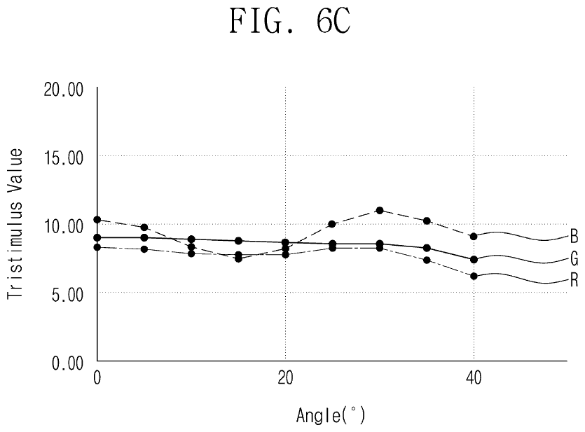

FIGS. 6A to 6C are graphs illustrating embodiment example 2 of Table 1. Specifically, FIG. 6A shows a reflection spectrum of a flat portion of embodiment example 2 described in Table 1, FIG. 6B shows reflection spectra at various angles of a bent portion of embodiment example 2 described in Table 1, and FIG. 6C shows tristimulus values of embodiment example 2 described in Table 1.

Referring to FIG. 6A, a reflectance of embodiment example 2 as a function of a wavelength is observed. When the wavelength is in a range greater than or equal to about 380 nm and smaller than or equal to about 740 nm, a maximum reflectance appears at the wavelength of about 380 nm and may be within a range greater than or equal to about 20% and smaller than or equal to about 25%. When the wavelength is in a range greater than or equal to about 430 nm and smaller than or equal to about 740 nm, the reflectance may be greater than or equal to about 0.1% and smaller than or equal to about 2%.

When the wavelength is in a range greater than or equal to about 380 nm and smaller than or equal to about 740 nm, a minimum reflectance may be formed at a first point a. The reflectance at the first point a may be greater than or equal to about 0.1% and smaller than or equal to about 0.3%. The first point a may be formed in the wavelength range greater than or equal to about 440 nm and smaller than or equal to about 460 nm.

When the wavelength is in a range greater than or equal to about 380 nm and smaller than or equal to about 740 nm, a second maximum reflectance may be formed at a second point b. The reflectance at the second point b may be greater than or equal to about 0.9% and smaller than or equal to about 1.5%. The second point b may be formed in the wavelength range greater than or equal to about 500 nm and smaller than or equal to about 520 nm. As the wavelength increases between the first point a and the second point b, the reflectance may increase.

When the wavelength is in a range greater than or equal to about 380 nm and smaller than or equal to about 740 nm, a second minimum reflectance may be formed at a third point c. The reflectance at the third point c may be greater than or equal to about 0.5% and smaller than or equal to about 1.0%. The third point c may be formed in the wavelength range greater than or equal to about 570 nm and smaller than or equal to about 590 nm. As the wavelength increases between the second point b and the third point c, the reflectance may decrease.

When the wavelength is in a range greater than or equal to about 380 nm and smaller than or equal to about 740 nm, a third maximum reflectance may be formed at a fourth point d. The reflectance at the fourth point d may be greater than or equal to about 0.8% and smaller than or equal to about 1.3%. The fourth point d may be formed in the wavelength range greater than or equal to about 660 nm and smaller than or equal to about 690 nm. As the wavelength increases between the third point c and the fourth point d, the reflectance may increase. As the wavelength increases in an area after the fourth point d, the reflectance may decrease.

FIG. 6B shows the graphs illustrating the reflection spectra measured at various angles of the bent portion BP shown in FIG. 5A. Specifically, a first graph GL1 shows the reflectance as a function of the wavelength when the bent portion BP is not bent, e.g., a bending angle of the bent portion BP is about 0°, a second graph GL2 shows the reflectance as a function of the wavelength when the bending angle of the bent portion BP is about 10°, a third graph GL3 shows the reflectance as a function of the wavelength when the bending angle of the bent portion BP is about 20°, a fourth graph GL4 shows the reflectance as a function of the wavelength when the bending angle of the bent portion BP is about 30°, and a fifth graph GL5 shows the reflectance as a function of the wavelength when the bending angle of the bent portion BP is about 40°.

FIG. 6C shows graphs illustrating the tristimulus values as a function of the bending angle of the bent portion BP, where the bent portion BP in this description may be the bent portion BP shown in FIG. 5A. Specifically, a red graph R represents an X value in an XYZ colorimetric system as a function of the bending angle of the bent portion BP, a green graph G represents a Y value in the XYZ colorimetric system as a function of the bending angle of the bent portion BP, and a blue graph B represents a Z value in the XYZ colorimetric system as a function of the bending angle of the bent portion BP.

Referring to FIG. 6B, it is observed that points of each of the first, second, third, and fourth graphs GL1, GL2, GL3, and GL4, which correspond to the first, second, third, and fourth points a, b, c, and d shown in FIG. 6A, shift to the left as the bending angle of the bent portion BP increases. Accordingly, as shown in FIG. 6C, it is observed that the tristimulus values according to the bending angle of the bent portion BP remain approximately constant near 10.00. That is, since there is almost no color difference with varying bending angles, the color perceived from the portion corresponding to the flat portion FP of the anti-reflective layer RPL and the color perceived from the portion corresponding to the bent portion BP of the anti-reflective layer RPL may be the same. Accordingly, the cover window CW of the present disclosure may have excellent reflectance while providing improved display quality.

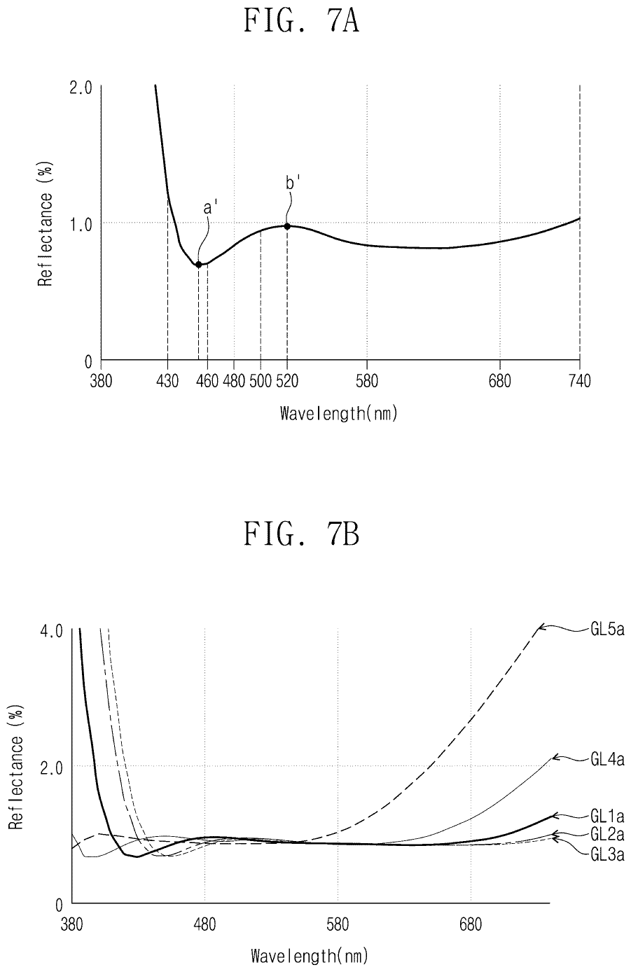

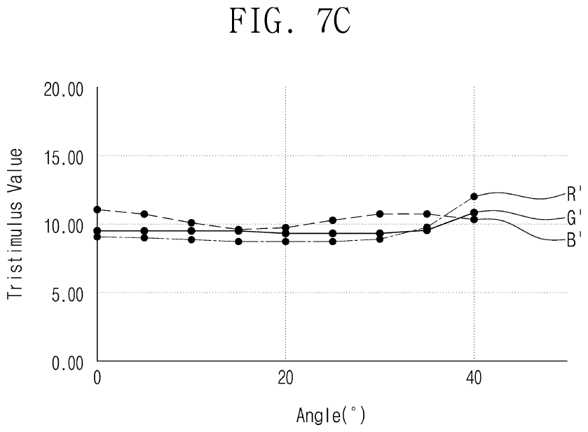

FIGS. 7A to 7C are graphs illustrating embodiment example 1 of Table 1. Specifically, FIG. 7A shows a reflection spectrum of a flat portion of embodiment example 1 described in Table 1, FIG. 7B shows reflection spectra at various angles of a bent portion of embodiment example 1 described in Table 1, and FIG. 7C shows tristimulus values of embodiment example 1 described in Table 1.

Referring to FIG. 7A, a reflectance of embodiment example 1 as a function of a wavelength is observed. When the wavelength is in a range greater than or equal to about 380 nm and smaller than or equal to about 740 nm, a maximum reflectance appears at the wavelength of about 380 nm and may be within a range greater than or equal to about 20% and smaller than or equal to about 25%. When the wavelength is in a range greater than or equal to about 430 nm and smaller than or equal to about 740 nm, the reflectance may be greater than or equal to about 0.1% and smaller than or equal to about 2%.

When the wavelength is in the range greater than or equal to about 380 nm and smaller than or equal to about 740 nm, a minimum reflectance may be formed at a first point a′. The reflectance at the first point a′ may be greater than or equal to about 0.1% and smaller than or equal to about 0.8%. The first point a′ may be formed in the wavelength range greater than or equal to about 430 nm and smaller than or equal to about 460 nm.

When the wavelength is in the range greater than or equal to about 380 nm and smaller than or equal to about 740 nm, a second maximum reflectance may be formed at a second point b′. The reflectance at the second point b′ may be greater than or equal to about 0.8% and smaller than or equal to about 1.0%. The second point b′ may be formed in the wavelength range greater than or equal to about 500 nm and smaller than or equal to about 520 nm. As the wavelength increases between the first point a′ and the second point b′, the reflectance may increase. As the wavelength increases in an area after the second point b′, the reflectance may decrease and then increase again. However, different from the graph shown in FIG. 7A, even when the wavelength increases in the area after the second point b′, the reflectance may remain constant.

FIG. 7B shows graphs illustrating the reflection spectra measured at various angles of the bent portion BP shown in FIG. 5A. Specifically, a first graph GL1a shows the reflectance as a function of the wavelength when the bent portion BP is not bent, e.g., a bending angle of the bent portion BP is about 0°, a second graph GL2a shows the reflectance as a function of the wavelength when the bending angle of the bent portion BP is 10°, a third graph GL3a shows the reflectance as a function of the wavelength when the bending angle of the bent portion BP is 20°, a fourth graph GL4a shows the reflectance as a function of the wavelength when the bending angle of the bent portion BP is 30°, and a fifth graph GL5a shows the reflectance as a function of the wavelength when the bending angle of the bent portion BP is 40°.

FIG. 7C shows graphs illustrating the tristimulus values as a function of the bending angle of the bent portion BP, where the bent portion BP in this description may be the bent portion BP shown in FIG. 5A. Specifically, a red graph R′ represents an X value in an XYZ colorimetric system as a function of the bending angle of the bent portion BP, a green graph G′ represents a Y value in the XYZ colorimetric system as a function of the bending angle of the bent portion BP, and a blue graph B′ represents a Z value in the XYZ colorimetric system as a function of the bending angle of the bent portion BP.

Referring to FIGS. 7B and 7C, it is observed that points of each of the first, second, third, and fourth graphs GL1a, GL2a, GL3a, and GL4a, which correspond to the first and second points a′ and b′ shown in FIG. 7A, shift to the left as the bending angle of the bent portion BP increases. Accordingly, as shown in FIG. 7C, it is observed that the tristimulus values according to the bending angle of the bent portion BP remain approximately constant near 10.00.

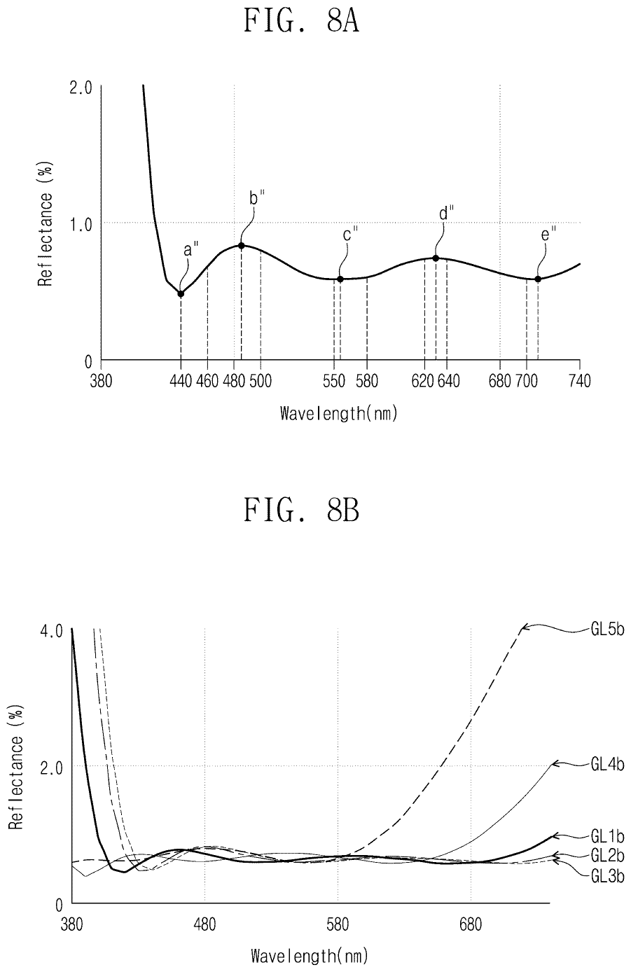

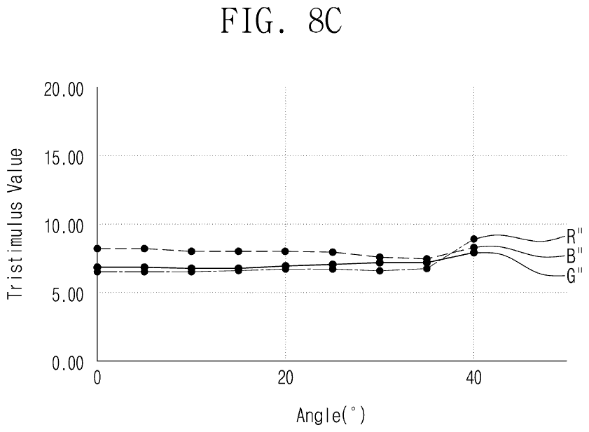

FIGS. 8A to 8C are graphs illustrating embodiment example 3 of Table 1. Specifically, FIG. 8A shows a reflection spectrum of a flat portion of embodiment example 3 described in Table 1, FIG. 8B shows reflection spectra at various angles of a bent portion of embodiment example 3 described in Table 1, and FIG. 8C shows tristimulus values of embodiment example 3 described in Table 1.

Referring to FIG. 8A, a reflectance of embodiment example 3 as a function of a wavelength is observed. When the wavelength is in a range greater than or equal to about 380 nm and smaller than or equal to about 740 nm, a maximum reflectance appears at the wavelength of about 380 nm and may be within a range greater than or equal to about 20% and smaller than or equal to about 25%. When the wavelength is in a range greater than or equal to about 430 nm and smaller than or equal to about 740 nm, the reflectance may be greater than or equal to about 0.1% and smaller than or equal to about 2%.

When the wavelength is in the range greater than or equal to about 380 nm and smaller than or equal to about 740 nm, a minimum reflectance may be formed at a first point a″. The reflectance at the first point a″ may be greater than or equal to about 0.3% and smaller than or equal to about 0.6%. The first point a″ may be formed in the wavelength range greater than or equal to about 440 nm and smaller than or equal to about 460 nm.

When the wavelength is in the range greater than or equal to about 380 nm and smaller than or equal to about 740 nm, a second maximum reflectance may be formed at a second point b″. The reflectance at the second point b″ may be greater than or equal to about 0.6% and smaller than or equal to about 0.9%. The second point b″ may be formed in the wavelength range greater than or equal to about 480 nm and smaller than or equal to about 500 nm. As the wavelength increases between the first point a″ and the second point b″, the reflectance may increase.

When the wavelength is in the range greater than or equal to about 380 nm and smaller than or equal to about 740 nm, a second minimum reflectance may be formed at a third point c″. The reflectance at the third point c″ may be greater than or equal to about 0.4% and smaller than or equal to about 0.7%. The third point c″ may be formed in the wavelength range greater than or equal to about 550 nm and smaller than or equal to about 580 nm. As the wavelength increases between the second point b″ and the third point c″, the reflectance may decrease.

When the wavelength is in the range greater than or equal to about 380 nm and smaller than or equal to about 740 nm, a third maximum reflectance may be formed at a fourth point d″. The reflectance at the fourth point d″ may be greater than or equal to about 0.6% and smaller than or equal to about 0.9%. The fourth point d″ may be formed in the wavelength range greater than or equal to about 620 nm and smaller than or equal to about 640 nm. As the wavelength increases between the third point c″ and the fourth point d″, the reflectance may increase.

When the wavelength is in the range greater than or equal to about 380 nm and smaller than or equal to about 740 nm, a third minimum reflectance may be formed at a fifth point e″. The reflectance at the fifth point e″ may be greater than or equal to about 0.4% and smaller than or equal to about 0.7%. The fifth point e″ may be formed in the wavelength range greater than or equal to about 700 nm and smaller than or equal to about 740 nm. As the wavelength increases in an area after the fifth point e″, the reflectance may increase.

FIG. 8B shows graphs illustrating the reflection spectra measured at various angles of the bent portion BP shown in FIG. 5A. Specifically, a first graph GL1b shows the reflectance as a function of the wavelength when the bent portion BP is not bent, e.g., a bending angle of the bent portion BP is about 0°, a second graph GL2b shows the reflectance as a function of the wavelength when the bending angle of the bent portion BP is 10°, a third graph GL3b shows the reflectance as a function of the wavelength when the bending angle of the bent portion BP is 20°, a fourth graph GL4b shows the reflectance as a function of the wavelength when the bending angle of the bent portion BP is 30°, and a fifth graph GL5b shows the reflectance as a function of the wavelength when the bending angle of the bent portion BP is 40°.

FIG. 8C shows graphs representing the tristimulus values as a function of the bending angle of the bent portion BP, where the bent portion BP in this description may be the bent portion BP shown in FIG. 5A. Specifically, a red graph R″ represents an X value in an XYZ colorimetric system as a function of the bending angle of the bent portion BP, a green graph G″ represents a Y value in the XYZ colorimetric system as a function of the bending angle of the bent portion BP, and a blue graph B″ represents a Z value in the XYZ colorimetric system as a function of the bending angle of the bent portion BP.

Referring to FIGS. 8B and 8C, it is observed that points of each of the first, second, third, and fourth graphs GL1b, GL2b, GL3b, and GL4b, which correspond to the first, second, third, and fourth points a″, b″, c″, and d″ shown in FIG. 8A, shift to the left as the bending angle of the bent portion BP increases. Accordingly, as shown in FIG. 8C, it is observed that the tristimulus values according to the bending angle of the bent portion BP remain approximately constant near 10.00.

Although the embodiments of the present disclosure have been described, it is understood that the present disclosure is not be limited to these embodiments and that various changes and modifications can be made by a person ordinarily skilled in the art within the spirit and scope of the present disclosure as hereinafter claimed. Therefore, the disclosed subject matter should not be limited to any single embodiment described herein.

What is claimed is:

1. A display device comprising:
a display panel comprising a light emitting element; and
a cover window disposed on the display panel and comprising a flat portion and a bent portion bent from an edge of the flat portion, the cover window comprising:
a base layer; and
an anti-reflective layer disposed on the base layer and comprising a high refractive index layer and a low refractive index layer disposed on the high refractive index layer,
wherein when a light is received on the cover window, a reflectance of the anti-reflective layer decreases as a wavelength of the light increases from about 380 nm to about 450 nm and also from about 500 nm to about 580 nm.

2. The display device of claim 1, wherein the low refractive index layer further comprises:
a first low refractive index layer disposed on the high refractive index layer; and
a second low refractive index layer disposed under the high refractive index layer such that the high refractive index layer separates the first low refractive index layer and the second low refractive index layer.

3. The display device of claim 2, wherein the first low refractive index layer has a refractive index in a range from about 1.45 to about 1.5, the high refractive index layer has a refractive index in a range from about 1.8 to about 2.1, and the second low refractive index layer has a refractive index in a range from about 1.45 to about 1.7.

4. The display device of claim 2, wherein the first low refractive index layer has a first thickness, the high refractive index layer has a second thickness, and the first thickness is greater than the second thickness.

5. The display device of claim 4, wherein the second low refractive index layer has a third thickness, and the second thickness is greater than the third thickness.

6. The display device of claim 1, wherein the anti-reflective layer has a maximum reflectance in a range from about 20% to about 30% when the wavelength of the light is in a range from about 380 nm to about 740 nm.

7. The display device of claim 1, wherein the anti-reflective layer has a minimum reflectance where the wavelength of the light is in a range from about 440 nm to about 460 nm.

8. The display device of claim 1, wherein the anti-reflective layer has a minimum reflectance that is in a range from about 0.1% to about 0.3%.

9. The display device of claim 1, wherein the reflectance of the anti-reflective layer increases as the wavelength of the light increases from about 460 nm to about 500 nm.

10. The display device of claim 1, wherein the reflectance of the anti-reflective layer increases as the wavelength of the light increases from about 580 nm to about 680 nm.

11. The display device of claim 1, wherein the reflectance of the anti-reflective layer decreases as the wavelength of the light increases from about 680 nm to about 740 nm.

12. The display device of claim 1, wherein the high refractive index layer is a first high refractive index layer of a plurality of high refractive index layers and the low refractive index layer is a first low refractive index layer of a plurality of low refractive index layers, the plurality of high refractive index layers being arranged to alternate with the plurality of low refractive index layers.

13. The display device of claim 12, wherein a thickness ratio between the first low refractive index layer of the plurality of low refractive index layers and the first high refractive index layer of the plurality of high refractive index layers is in a range from about 1.25 to about 1.68, the first low refractive index layer being directly above the first high refractive index layer and being further from the base layer than all other low refractive index layers of the plurality of low refractive index layers.

14. The display device of claim 1, wherein the flat portion has a thickness greater than a thickness of the bent portion.

15. The display device of claim 1, wherein the cover window further comprises a functional layer disposed on the anti-reflective layer, the functional layer comprising at least one of an antistatic agent, a hard coating agent, and an anti-fingerprint agent.

16. A display device comprising:
a display panel comprising a light emitting element; and
a cover window disposed on the display panel, the cover window comprising:
a base layer; and
an anti-reflective layer disposed on the base layer and comprising a first refractive index layer, a second refractive index layer disposed under the first refractive index layer, and a third refractive index layer disposed under the second refractive index layer, the first refractive index layer being further from the base layer than the third refractive index layer,
wherein a refractive index of the second refractive index layer is greater than a refractive index of the first refractive index layer and a refractive index of the third refractive index layer, the refractive index of the first refractive index layer being different from the refractive index of the third refractive index layer, and
wherein the first refractive index layer has a first thickness greater than a second thickness of the second refractive index layer, and the second thickness of the second refractive index layer is greater than a third thickness of the third refractive index layer.

17. The display device of claim 16, wherein the refractive index of the first refractive index layer is in a range from about 1.45 to about 1.5, the refractive index of the second refractive index layer is in a range from about 1.8 to about 2.1, and the refractive index of the third refractive index layer is in a range from about 1.45 to about 1.7.

18. The display device of claim 16, wherein a reflectance of the anti-reflective layer decreases as a wavelength of a light received on the cover window increases from about 380 nm to about 450 nm and also from about 500 nm to about 580 nm.

19. The display device of claim 16, wherein the anti-reflective layer has a minimum reflectance where a wavelength of a light received on the cover window is in a range from about 440 nm to about 460 nm, and the minimum reflectance is in a range from about 0.1% to about 0.3%.

20. An electronic device comprising:
a display device in which a module area is defined; and
an electronic module disposed to correspond to the module area, the display device comprising:
a display panel comprising a light emitting element; and
a cover window disposed on the display panel and comprising a flat portion and a bent portion bent from an edge of the flat portion, the cover window comprising:
a base layer; and
an anti-reflective layer disposed on the base layer and comprising a high refractive index layer and a low refractive index layer disposed on the high refractive index layer,
wherein when a light is received on the cover window, a reflectance of the anti-reflective layer decreases as a wavelength of the light increases from about 380 nm to about 450 nm and also from about 500 nm to about 580 nm.
